(19) United States
(12) Patent Application Publication
(10) Pub. No.: US 2021/0123136 A1
(43) Pub. Date: Apr. 29, 2021

(54) Methods To Grow Low Resistivity Metal Containing Films

(71) Applicant: Applied Materials, Inc., Santa Clara, CA (US)

(72) Inventors: Lakmal C. Kalutarage, San Jose, CA (US); Liqi Wu, San Jose, CA (US); Pratham Jain, Santa Clara, CA (US); Jeffrey W. Anthis, San Jose, CA (US); Mark Saly, Santa Clara, CA (US); Mei Chang, Saratoga, CA (US); David Thompson, San Jose, CA (US)

(73) Assignee: Applied Materials, Inc., Santa Clara, CA (US)

(21) Appl. No.: 17/084,184

(22) Filed: Oct. 29, 2020

Related U.S. Application Data
(60) Provisional application No. 62/927,676, filed on Oct. 29, 2019.

(51) Int. Cl. C23C 16/455; H01L 21/285; C23C 16/34; C23C 16/56

(52) U.S. Cl. CPC C23C 16/45527; H01L 21/28568; C23C 16/56; C23C 16/34; H01L 21/28556

(57) ABSTRACT

The use of a cyclic 1,4-diene reducing agent with a metal precursor and a reactant to form metal-containing films are described. Methods of forming the metal-containing film comprises exposing a substrate surface to a metal precursor, a reducing agent and a reactant either simultaneously, partially simultaneously or separately and sequentially to form the metal-containing film.

### CROSS-REFERENCE TO RELATED APPLICATIONS

This application claims priority to U.S. Provisional Application No. 62/927,676, filed Oct. 29, 2019, the entire disclosure of which is hereby incorporated by reference herein.

### TECHNICAL FIELD

Embodiments of the present disclosure generally relate to methods of depositing metal films. In particular, the disclosure relates to methods of providing metal films with low resistivity.

### BACKGROUND

Due to the miniaturization of microelectronic devices, semiconductor manufacturing is becoming a key inflection for materials innovation. Constant innovation of new materials and processes to deposit new materials are required. Two-dimensional metal-oxide semiconductor (MOS) transistor devices are shrinking in dimensions and moving toward fin shaped three-dimensional transistors. With the shrinking dimensions of the transistors, deposition of conformal thin films and tuning of the device threshold voltages are becoming more difficult.

Similarly, memory devices have decreasing dimensions with increased aspect ratios to a range the industry never seen before. Therefore, a deposition method like atomic layer deposition (ALD) is often preferred due to an inherent surface limited growth process. In addition, thermal ALD is often preferred because plasma based ALD processes lead to substrate damage and non-conformal films.

Titanium nitride (TiN) films are used in logic and memory applications. TiN is expected to be a barrier material for tungsten, ruthenium, and cobalt. Additionally, TiN is used as the high-K cap and as a p-metal material in gate stacks. Typically, thermal ALD TiN films are deposited by reacting titanium chloride (TiCl₄) and ammonia (NH₃) at temperatures greater than 400° C. in order to get appropriate resistivity the film.

Accordingly, there is a need for methods of depositing metal-containing films with low resistivity and/or good conformality on high aspect ratio structures. There is a need for methods of depositing metal-containing films at lower temperatures.

### SUMMARY

One or more embodiments of the disclosure are directed to methods of forming metal films. A substrate surface is exposed to a metal precursor having a metal with a first oxidation state. The substrate surface is exposed to a reducing agent to decrease the first oxidation state of the metal to a second oxidation state. The substrate surface is exposed to a reactant to form a metal-containing film comprising one or more of a metal nitride, metal carbide, metal silicide or metal oxide.

Additional embodiments of the disclosure are directed to methods of forming metal films. A substrate surface is exposed to a metal halide precursor having a metal with a first oxidation state to form a metal-containing layer on the substrate surface. The metal-containing layer on the substrate surface is exposed to a reducing agent to decrease the first oxidation state of the metal to a second oxidation state and form a reduced metal-containing layer on the substrate surface. The reduced metal-containing layer on the substrate surface is exposed to a reactant to form a metal-containing film comprising one or more of a metal nitride, metal carbide, metal silicide or metal oxide.

Further embodiments of the disclosure are directed to methods of forming metal films. A substrate surface is exposed to a metal precursor, a reducing agent and a reactant to form a metal-containing film comprising one or more of a metal nitride, metal carbide, metal silicide or metal oxide. The reducing agent comprises a compound having the formula

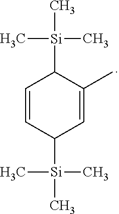

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Embodiments of the present disclosure relate to methods for depositing metal films. Some embodiments advantageously form metal nitride films with reduced resistivity. Some embodiments of the disclosure advantageously provide thermal atomic layer deposition (ALD) processes for depositing metal-containing films. As used in this manner, a “thermal” ALD process is an atomic layer deposition process in which a plasma reactant is not employed to deposit the film. A thermal ALD process can include a plasma based post-deposition process to control or modify some property of the film (e.g., density).

Some embodiments of the disclosure advantageously reduce the temperature to get a target resistivity and/or a lower overall resistivity. One or more embodiments of the disclosure provide methods for depositing films that reduce the metal center first to a lower oxidation state and then react with a reactant (e.g., ammonia). In some embodiments, the metal precursor, reducing agent and reactant are simultaneously exposed to a substrate. In some embodiments, the reducing agent is exposed to the substrate with one of the metal precursor or reactant.

In some embodiments, the metal precursor, reducing agent and reactant are exposed to the substrate separately and sequentially. For example, in some embodiments, the substrate surface or process chamber is purged of one reactive gas prior to exposure to the next reactive gas. While examples are given throughout this specification with respect to the formation of titanium films, the skilled artisan will recognize that the disclosure is not limited to titanium and that any suitable metal can be used, as described herein.

An exemplary process for forming a titanium nitride film comprises exposing the substrate to a titanium precursor (e.g., TiCl₄); purging the processing chamber or substrate surface of unreacted titanium precursor; exposing the substrate to a reducing agent; purging the processing chamber of substrate surface of unreacted reducing agent; exposing the substrate surface to a reactant (e.g., ammonia); and purging the processing chamber of substrate surface of unreacted reactant. Without being bound by any particular theory of operation, it is believed that once the titanium metal center in TiCl₄ is reduced (from 4+ to less than 4+ oxidation state), the newly formed titanium surface becomes much more reactive than 4+ oxidation state which allows ammonia to react with the surface faster and cleaner. (The Ti⁴⁺ oxidation state is the most stable form and less than 4+ is not as stable.)

In some embodiments, the reducing agent of some embodiments attracts Cl from TiCl₄, lower the chloride content of the film. It is believed that lowering the chloride content reduces film resistivity. In some embodiments, the metal precursor comprises a metal chloride and exposing the substrate surface to the reducing agent decreases a chlorine content of the film.

Scheme (I) depicts the reaction during one exemplary ALD cycle.

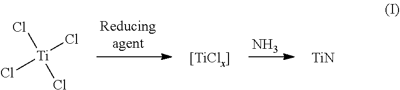

In some embodiments, the reducing agent comprises an organosilane reducing agent and the reaction between TiCl₄ and the reducing agent is believed to progress according to Scheme (II).

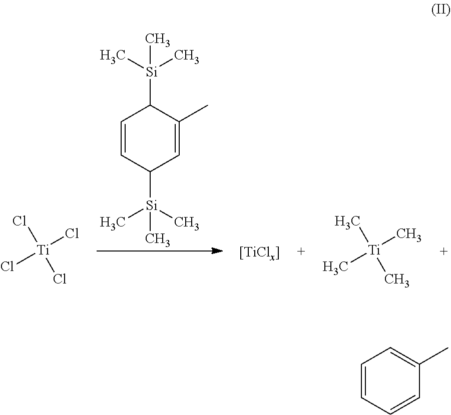

TiCl_{X} is believed to be unstable and reactive towards ammonia. The possible reaction with ammonia is shown in Scheme (III) below.

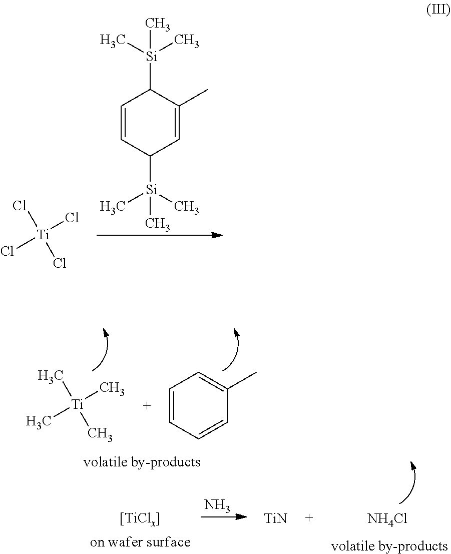

Accordingly, one or more embodiments of the disclosure are directed to methods of forming metal films. The metal films of some embodiments comprise metal atoms and one or more of nitrogen, carbon, silicon or oxygen atoms.

In some embodiments, the substrate surface is exposed to a metal precursor having a metal with a first oxidation state. The substrate surface is exposed to a reducing agent to decrease the first oxidation state of the metal to a second oxidation state. The substrate surface is exposed to a reactant to form a metal-containing film comprising one or more of a metal nitride, metal carbide, metal silicide or metal oxide. The metal precursor, reducing agent and reactant in some embodiments are exposed to the substrate at the same time. For example, in a chemical vapor deposition (CVD) process. In some embodiments, the reducing agent is exposed to the substrate surface at the same time as one of the metal precursor of the reactant. For example, in a hybrid chemical vapor deposition (CVD)-atomic layer deposition (ALD) process. In some embodiments, the metal precursor, reducing agent and reactant are separately and sequentially exposed to the substrate surface. For example, in an atomic layer deposition (ALD) process.

Some embodiments of the methods for forming metal films comprise exposing a substrate surface to a metal halide precursor having a metal with a first oxidation state to form a metal-containing layer on the substrate surface. The metal-containing layer on the substrate surface is exposed to a reducing agent to decrease the first oxidation state of the metal to a second oxidation state and form a reduced metal-containing layer on the substrate surface. The reduced metal-containing layer on the substrate surface is exposed to a reactant to form a metal-containing film comprising one or more of a metal nitride, metal carbide, metal silicide or metal oxide.

The metal precursor can be any suitable metal precursor. In some embodiments, the metal precursor comprises a metal halide having the general formula MXₐR_{b}, where M is a metal atom, each X is a halogen independently selected from F, Cl, Br and I, each R is independently selected from C1-C6 alkyl, N-donor ligands, CO and cyclopentadienyl groups, a is in the range of 0 to 6 and b is in the range of 0 to 6. As used in this manner, the term “C1-C6”, and use of ‘C’ followed by a numeral, means that the substituent group has the stated number of carbon atoms. For example, a C4 alkyl group has four carbon atoms. Suitable C4 alkyl groups include n-butyl, isobutyl, tert-butyl groups. In some embodiments, b is 0. In some embodiments, b is 0 and each X is the same element. As used in this manner, the term “each X is the same element” means that greater than or equal to about 95%, 98%, 99% or 99.5% of the halogen atoms comprise the stated atom.

This method can be extended to other metals and various metal precursors may be used to obtain low resistivity metal nitrides. The metal atom of the metal precursor comprises any suitable metal species. In some embodiments, the metal atom is selected from the group III through group XIV metals of the periodic table. Suitable metal species include, but are not limited to, scandium, yttrium, lanthanum, titanium, zirconium, hafnium, vanadium, niobium, tantalum, chromium, molybdenum, tungsten, manganese, technetium, rhenium, iron, ruthenium, osmium, cobalt, rhodium, iridium, nickel, palladium, platinum, copper, silver, gold, zinc, cadmium, boron, aluminum, gallium, indium, thallium, carbon, silicon, germanium, tin or lead.

In some embodiments, the metal atom is selected from the group consisting of titanium, gallium or tantalum. In some embodiments, the metal precursor comprises one or more of TiCl₄, TaCl₄ or GaCl₄. In some embodiments, the metal precursor consists essentially of one or more of TiCl₄, TaCl₄ or GaCl₄. As used in this manner, the term “consists essentially of” means that the reactive species of the metal precursor is greater than or equal to about 95%, 98%, 99% or 99.5% of the stated species on a molar basis. Inert of carrier gases are not considered in this calculation

In some embodiments, the reducing agent comprises one or more of a cyclic 1,4-diene, a silane, a carbosilane, a borane, an amino borane, a tin hydride, an aluminum hydride or a tin (II) compound.

In some embodiments, the reducing agent has the general formula

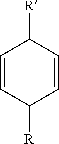

where each R and R′ are independently selected from H, C1-C6 alkyl groups, —NR″₂ groups and —SiR″₃, where R″ is selected from H, C1-C4 branched or unbranched alkyl groups.

In some embodiments, the reducing agent comprises or consists essentially of a compound with the general formula

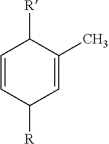

where each R and R′ are independently selected from H, C1-C6 alkyl groups, —NR″₂ groups and —SiR″₃, where R″ is selected from H, C1-C4 branched or unbranched alkyl groups

In some embodiments, the reducing agent comprises or consists essentially of reducing agent (A)

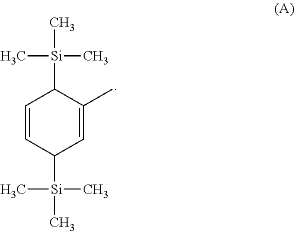

In some embodiments, the first oxidation state of the metal species is greater than or equal to 2+. In some embodiments, the first oxidation state of the metal species is greater than or equal to 3+, 4+, 5+ or 6+. In some embodiments, after exposure to the reducing agent the second oxidation state is less than or equal to 5+, 4+, 3+, 2+, 1+ or 0, and the second oxidation state is less than the first oxidation state.

In some embodiments, the same concept is used to deposit metal oxides, metal silicides, and metal carbides. In some embodiments, the reactant comprises one or more of one or more of a nitridation agent to form a metal nitride film, an oxidation agent to form a metal oxide film, siliciding agent to form a metal silicide film or a carbiding agent to form a metal carbide film.

In some embodiments, the reactant comprises a nitridation agent. The nitridation agent of some embodiments comprises or consists essentially of ammonia. In some embodiments, nitridation agents other than ammonia are used. Suitable nitridation agents include, but are not limited to, hydrazines, amines, nitridation plasmas can be used. In some embodiments, the reactant comprises one or more of ammonia, a hydrazine, an amine or a nitriding plasma.

In some embodiments, a metal oxide film is formed. For example, after reduction of the metal species by the reducing agent, the metal species is exposed to an oxidizing agent. Suitable oxidizing agents include, but are not limited to, water, O₂, O₃, peroxide, alcohol, or an oxidizing plasma. Without being bound by theory, it is believed that because of the high reactivity of surface species oxidizing agent can readily react with the surface which may lead to cleaner reaction than reacting with the surface absorbed/chemisorbed metal precursor without a reducing agent; leading to a purer metal oxide film.

In some embodiments, a metal carbide film is formed. In order to obtain metal carbides, first the metal precursor can be reduced with a reducing agent and form reactive species on the wafer surface. After that a carbon molecule exposure will convert the surface to metal carbides. During this step a plasma treatment also may be used.

In some embodiments, a metal silicide film is formed. To obtain metal silicides, a silane or carbo-silane can be exposed to the surface obtained after reacting a metal precursor and a reducing agent. In particular, TiSi which can be used as contact material can be formed by reacting TiCl4 and A. Temperatures above 400 C silicon tends to diffuse and TiSi can be formed. By introducing a silane after TiCl4 and A can deposit TiSi. This can be done with ALD pulsed manner or by co-flowing precursors together. H2 may be used to facilitate the reactions. Above TiSi formation will occur on cleaned Si but not on SiO or SiN which is a requirement for contact material.

In some embodiments, the metal content of the metal-containing film is controlled by the reducing agent and/or the reactant. In some embodiments, the metal-containing film comprises a metal rich metal-containing film. As used in this manner, the term “metal-rich” and the like, means that the metal content of the film is greater than would be expected based on the stoichiometric ratio of atoms in the film. In some embodiments, the metal-containing film comprises a titanium rich titanium nitride film. In some embodiments, the metal-containing film comprises a tantalum rich tantalum nitride film.

In some embodiments, the substrate surface is exposed to hydrogen (H₂) to decrease resistivity of the metal-containing film and/or reduce contaminants in the metal-containing film. In some embodiments, the hydrogen exposure is a post-treatment process performed after a predetermined number of deposition cycles. Each deposition cycle comprises exposures to the metal precursor, the reducing agent and the reactant.

In some embodiments, a mixed metal-containing film is formed. In some embodiments, the method further comprises exposing the substrate surface to more than one metal species from one or more of the metal precursor, reducing agent or reactant to form one or more of a mixed metal nitride, a mixed metal oxide, a mixed metal carbide or a mixed metal silicide film. The mixed metal of some embodiments is provided by using a mixed metal precursor (e.g., a mixture of TiCl₄ and TaCl₄ to give a mixed TiTa film). In some embodiments, one of or more of the metals are provided by the reducing agent or reactant.

The metal-containing films of some embodiments are deposited at temperatures less than or equal to about 500° C., 450° C., 400° C., 350° C., 300° C., 250° C., 200° C., 150° C. or 100° C.

A generic methodology for formation of the metal-containing film according to some embodiments comprises vaporizing a metal precursor to an ALD chamber followed by inert purge of excess metal precursor and by-products. Then, a reducing agent is vaporized and flowed to the chamber. When the reducing agent interacts with surface bound metal precursor species, the metal center gets reduced to a lower oxidation state and a reactive surface is formed. Then, an inert gas purge is applied to remove all unreacted molecules and by-products. After that, a nitridation agent such as ammonia is delivered to the chamber. Ammonia reacts with the surface to form metal nitride film. This cycle can be repeated as many times to get the desired thickness. The chamber pressure and temperature can be maintained from 1 torr to 10 torr and 100 C to 500 C, respectively.

### Example: Deposition of TiN Films

TiCl₄, reducing agent A and ammonia were employed in ALD fashion to deposit low resistivity TiN films. A silicon oxide substrate was heated to 400° C. in an ALD chamber. Then ALD pulse sequence was carried out as follows; TiCl₄ pulse of 0.3 seconds followed by 10 s nitrogen purge, 2 s pulse of reducing agent A, followed by 10 s nitrogen purge, and 6 s pulse of ammonia followed by 30 s nitrogen purge. The cycle was repeated to deposit a film with a predetermined thickness. This process was carried out at different temperatures and, growth rate and resistivities were measured. Comparison of growth rate along with resistivity data from above-mentioned procedure and the baseline process (TiN without reducing agent A) showed a clear increase in growth rate and decrease in resistivity. Compositional analysis of the films showed an increase in the titanium to nitrogen ratio.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a metal film, the method comprising:
exposing a substrate surface to a metal precursor, the metal precursor having a metal with a first oxidation state;
exposing the substrate surface to a reducing agent to decrease the first oxidation state of the metal to a second oxidation state; and
exposing the substrate surface to a reactant to form a metal-containing film comprising one or more of a metal nitride, metal carbide, metal silicide or metal oxide.

2. The method of claim 1, wherein the metal precursor comprises a metal halide having the general formula MXₐR_{b}, where M is a metal atom, each X is a halogen independently selected from F, Cl, Br and I, each R is independently selected from C1-C6 alkyl, N-donor ligands, CO and cyclopentadienyl groups, a is in the range of 0 to 6 and b is in the range of 0 to 6.

3. The method of claim 2, wherein the metal atom is selected from the group III through group XIV metals of the periodic table.

4. The method of claim 3, wherein the metal atom is selected from the group consisting of titanium, gallium or tantalum.

5. The method of claim 4, wherein the metal precursor comprises one or more of TiCl₄, TaCl₄ or GaCl₄.

6. The method of claim 1, wherein the reducing agent comprises one or more of a cyclic 1,4-diene, a silane, a carbosilane, a borane, an amino borane, a tin hydride, an aluminum hydride or a tin (II) compound.

7. The method of claim 6, wherein the reducing agent has the general formula 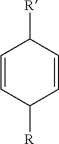
where each R and R′ are independently selected from H, C1-C6 alkyl groups, —NR″₂ groups and —SiR″₃, where R″ is selected from H, C1-C4 branched or unbranched alkyl groups.

8. The method of claim 6, wherein the reducing agent has the general formula 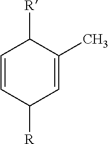
where each R and R′ are independently selected from H, C1-C6 alkyl groups, —NR″₂ groups and —SiR″₃, where R″ is selected from H, C1-C4 branched or unbranched alkyl groups

9. The method of claim 6, wherein the reducing agent comprises

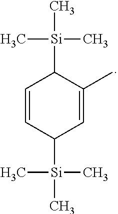

10. The method of claim 9, wherein the metal precursor comprises a metal chloride and exposing the substrate surface to the reducing agent decreases a chlorine content of the film.

11. The method of claim 1, wherein the reactant comprises one or more of one or more of a nitridation agent to form a metal nitride film, an oxidation agent to form a metal oxide film, siliciding agent to form a metal silicide film or a carbiding agent to form a metal carbide film.

12. The method of claim 1, wherein the metal-containing film comprises a metal rich metal nitride film.

13. The method of claim 1, wherein the first oxidation state is greater than or equal to 2+.

14. The method of claim 1, wherein the reactant comprises one or more of ammonia, a hydrazine, an amine or a nitriding plasma.

15. The method of claim 1, further comprising exposing the substrate surface to hydrogen (H₂) to decrease resistivity of the metal-containing film and/or reduce contaminants in the metal-containing film.

16. The method of claim 1, wherein the substrate surface is sequentially and separately exposed to the metal precursor, the reducing agent and the reactant.

17. The method of claim 1, wherein the substrate surface is exposed to a coflow of two or more of the metal precursor, the reducing agent or the reactant.

18. The method of claim 1, further comprising exposing the substrate surface to more than one metal species from one or more of the metal precursor, reducing agent or reactant to form one or more of a mixed metal nitride, a mixed metal oxide, a mixed metal carbide or a mixed metal silicide film.

19. A method of forming a metal film, the method comprising:
exposing a substrate surface to a metal halide precursor having a metal with a first oxidation state to form a metal-containing layer on the substrate surface;
exposing the metal-containing layer on the substrate surface to a reducing agent to decrease the first oxidation state of the metal to a second oxidation state and form a reduced metal-containing layer on the substrate surface; and
exposing the reduced metal-containing layer on the substrate surface to a reactant to form a metal-containing film comprising one or more of a metal nitride, metal carbide, metal silicide or metal oxide.

20. A method of forming a metal film, the method comprising:
exposing a substrate surface to a metal precursor, a reducing agent and a reactant to form a metal-containing film comprising one or more of a metal nitride, metal carbide, metal silicide or metal oxide, the reducing agent comprising [chemical structure]
